(19) United States
(12) Patent Application Publication
(10) Pub. No.: US 2026/0076237 A1
(43) Pub. Date: Mar. 12, 2026

(54) SEMICONDUCTOR INTERPOSERS WITH LAYER STACKUP FEATURES

(71) Applicant: Raytheon Company, Arlington, VA (US)

(72) Inventors: Jason G. Milne, El Segundo, CA (US); Aaron George, San Diego, CA (US); Eric R. Miller, Orcutt, CA (US); Amada M. Castro, El Segundo, CA (US)

(21) Appl. No.: 19/319,530

(22) Filed: Sep. 4, 2025

Related U.S. Application Data
(60) Provisional application No. 63/692,562, filed on Sep. 9, 2024.

(51) Int. Cl. H01L 23/498; H01L 21/48; H01L 23/538; H01L 23/64

(52) U.S. Cl. CPC H10W 70/685; H10W 44/401; H10W 70/05; H10W 70/611; H10W 70/65; H10W 90/701

(57) ABSTRACT

An apparatus includes an interposer configured to be electrically coupled to one or more semiconductor devices. The interposer includes a core having a substrate and first vias through the substrate, a first stackup of layers over a first side of the core, and a second stackup of layers over a second side of the core. The first stackup of layers includes first redistribution layers and first dielectric layers. The first redistribution layers are electrically coupled together using second vias through the first dielectric layers, and the first stackup of layers forms a first and a second stripline. The second stackup of layers includes second redistribution layers and second dielectric layers. The second redistribution layers are electrically coupled together using third vias through the second dielectric layers, and the second stackup of layers forms a third stripline.

### CROSS-REFERENCE TO RELATED APPLICATION AND PRIORITY CLAIM

This application claims priority under 35 U.S.C. § 119(e) to U.S. Provisional Patent Application No. 63/692,562 filed on Sep. 9, 2024, which is hereby incorporated by reference in its entirety.

### TECHNICAL FIELD

This disclosure is generally directed to electronic devices, systems, and processes. More specifically, this disclosure is directed to semiconductor interposers with layer stackup features.

### BACKGROUND

Device packaging has become a primary focus of investment as electronic device manufacturers have embraced multi-chip/multi-core approaches in which die-to-die and die-to-package interconnectivity is a significant driver of performance. Interposers have become a common way to connect semiconductor dies. For example, interposers can be used to connect semiconductor dies to one another and/or to package substrates or printed circuit boards (PCBs).

### SUMMARY

This disclosure relates to semiconductor interposers with layer stackup features.

In a first example embodiment, an apparatus includes an interposer configured to be electrically coupled to one or more semiconductor devices. The interposer includes a core, a first stackup of layers over a first side of the core, and a second stackup of layers over a second side of the core opposite the first side. The core includes a substrate and first vias through the substrate. The first stackup of layers includes first redistribution layers and first dielectric layers. The first redistribution layers are electrically coupled together using second vias through the first dielectric layers, and the first stackup of layers forms a first stripline and a second stripline. The second stackup of layers includes second redistribution layers and second dielectric layers. The second redistribution layers are electrically coupled together using third vias through the second dielectric layers, and the second stackup of layers forms a third stripline.

Any single one or any combination of the following features may be used with the first example embodiment. At least some of the first, second, and third vias may be stacked to form direct electrical pathways straight through the interposer. The first dielectric layers may be thicker than the first redistribution layers. The second dielectric layers may be thicker than the second redistribution layers. Each of the first dielectric layers and the second dielectric layers may include a material having a dielectric constant between about 1 and about 12. The first stackup of layers may include at least five first redistribution layers separated by at least four first dielectric layers. The second stackup of layers may include at least three second redistribution layers separated by at least two second dielectric layers. The first redistribution layers may alternate between having a thickness of about twice a base value and about the base value. Each of the first dielectric layers may have a thickness of about three times the base value. The second redistribution layers may alternate between having a thickness of about twice the base value and about the base value. Each of the second dielectric layers may have a thickness of about three times the base value. The base value may be between about 0.5 microns and about 2 microns. The base value may be about 1 micron. Each of the second vias and the third vias may have a diameter of about 3 microns. Each of a plurality of conductive portions of the first redistribution layers contacting the second vias and each of a plurality of conductive portions of the second redistribution layers contacting the third vias may have a diameter of about 4 microns. Each stackup of layers may include at least one of: one or more embedded resistors, each having a sheet resistance value between about 1 and about 1,000 Ohms/square, or one or more embedded capacitors, each including a dielectric material having a dielectric constant between about 1 and about 100. The interposer may include first electrical connectors over and electrically coupled to the first stackup of layers and second electrical connectors over and electrically coupled to the second stackup of layers. The first stripline may form a first transmission or impedance line, the second stripline may form a second transmission or impedance line, the third stripline may form a third transmission or impedance line, and each of the first, second, and third transmission or impedance lines may have a specified impedance. Each of the first stripline and the second stripline may form a single-ended transmission line, or the first stripline and the second stripline may together form a differential transmission line. Each stackup of layers may include a high-density stackup of layers configured to implement a digital communication protocol between at least one of: two or more semiconductor devices or portions of a single semiconductor device. The first redistribution layers may have a ground-signal-ground-signal-ground pattern such that the first stripline and the second stripline share a common ground, and the second redistribution layers have a ground-signal-ground pattern.

In a second example embodiment, a system includes one or more semiconductor devices and a package enclosing the one or more semiconductor devices. The package includes an interposer electrically coupled to the one or more semiconductor devices. The interposer includes a core, a first stackup of layers over a first side of the core, and a second stackup of layers over a second side of the core opposite the first side. The core includes a substrate and first vias through the substrate. The first stackup of layers includes first redistribution layers and first dielectric layers. The first redistribution layers are electrically coupled together using second vias through the first dielectric layers, and the first stackup of layers forms a first stripline and a second stripline. The second stackup of layers includes second redistribution layers and second dielectric layers. The second redistribution layers are electrically coupled together using third vias through the second dielectric layers, and the second stackup of layers forms a third stripline.

Any single one or any combination of the following features may be used with the second example embodiment. The first redistribution layers may alternate between having a thickness of about twice a base value and about the base value. Each of the first dielectric layers may have a thickness of about three times the base value. The second redistribution layers may alternate between having a thickness of about twice the base value and about the base value. Each of the second dielectric layers may have a thickness of about three times the base value. The base value may be between about 0.5 microns and about 2 microns. The base value may be about 1 micron. Each of the second vias and the third vias may have a diameter of about 3 microns. Each of a plurality of conductive portions of the first redistribution layers contacting the second vias and each of a plurality of conductive portions of the second redistribution layers contacting the third vias may have a diameter of about 4 microns. Each stackup of layers may include at least one of: one or more embedded resistors, each having a sheet resistance value between about 1 and about 1,000 Ohms/square, or one or more embedded capacitors, each including a dielectric material having a dielectric constant between about 1 and about 100. The package may include a package substrate, a stiffener, and a lid. The stiffener may be mounted on the package substrate and positioned at least partially around the interposer. The lid may be attached to the stiffener to define an interior space between the lid, the stiffener, and the package substrate. The one or more semiconductor devices and the interposer may be positioned within the interior space. The system may include a printed circuit board on which the package is mounted. The interposer may be configured to facilitate communication between the one or more semiconductor devices and the printed circuit board. Each stackup of layers may include a high-density stackup of layers configured to implement a digital communication protocol between at least one of: two or more semiconductor devices or two or more connectors of a single semiconductor device.

In a third example embodiment, a method includes obtaining a core having a substrate and first vias through the substrate. The method also includes forming a first stackup of layers over a first side of the core. The first stackup of layers includes first redistribution layers and first dielectric layers. The first redistribution layers are electrically coupled together using second vias through the first dielectric layers, and the first stackup of layers forms a first stripline and a second stripline. The method further includes forming a second stackup of layers over a second side of the core opposite the first side. The second stackup of layers includes second redistribution layers and second dielectric layers. The second redistribution layers are electrically coupled together using third vias through the second dielectric layers, and the second stackup of layers forms a third stripline.

Any single one or any combination of the following features may be used with the third example embodiment. At least some of the first, second, and third vias may be stacked to form direct electrical pathways straight through the interposer. The first dielectric layers may be thicker than the first redistribution layers. The second dielectric layers may be thicker than the second redistribution layers. Each of the first dielectric layers and the second dielectric layers may include a material having a dielectric constant between about 1 and about 12. The first stackup of layers may include at least five first redistribution layers separated by at least four first dielectric layers. The second stackup of layers may include at least three second redistribution layers separated by at least two second dielectric layers. The first redistribution layers may alternate between having a thickness of about twice a base value and about the base value. Each of the first dielectric layers may have a thickness of about three times the base value. The second redistribution layers may alternate between having a thickness of about twice the base value and about the base value. Each of the second dielectric layers may have a thickness of about three times the base value. The base value may be between about 0.5 microns and about 2 microns. The base value may be about 1 micron. Each of the second vias and the third vias may have a diameter of about 3 microns. Each of a plurality of conductive portions of the first redistribution layers contacting the second vias and each of a plurality of conductive portions of the second redistribution layers contacting the third vias may have a diameter of about 4 microns. Each stackup of layers may include at least one of: one or more embedded resistors, each having a sheet resistance value between about 1 and about 1,000 Ohms/square, or one or more embedded capacitors, each including a dielectric material having a dielectric constant between about 1 and about 100. The interposer may include first electrical connectors over and electrically coupled to the first stackup of layers and second electrical connectors over and electrically coupled to the second stackup of layers. The first stripline may form a first transmission or impedance line, the second stripline may form a second transmission or impedance line, the third stripline may form a third transmission or impedance line, and each of the first, second, and third transmission or impedance lines may have a specified impedance. Each of the first stripline and the second stripline may form a single-ended transmission line, or the first stripline and the second stripline may together form a differential transmission line. Each stackup of layers may include a high-density stackup of layers configured to implement a digital communication protocol between at least one of: two or more semiconductor devices or portions of a single semiconductor device. The first redistribution layers may have a ground-signal-ground-signal-ground pattern such that the first stripline and the second stripline share a common ground, and the second redistribution layers have a ground-signal-ground pattern.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIG. 1 illustrates an example of a semiconductor die package according to this disclosure;

FIGS. 2A and 2B illustrate examples of semiconductor interposers with layer stackup features according to this disclosure;

FIG. 3 illustrates a cross-sectional view of an example of a portion of a semiconductor interposer with layer stackup features according to this disclosure;

FIG. 4 illustrates examples of connection options for a semiconductor interposer with layer stackup features according to this disclosure; and

FIG. 5 illustrates an example of a method for forming a semiconductor interposer with layer stackup features according to this disclosure.

### DETAILED DESCRIPTION

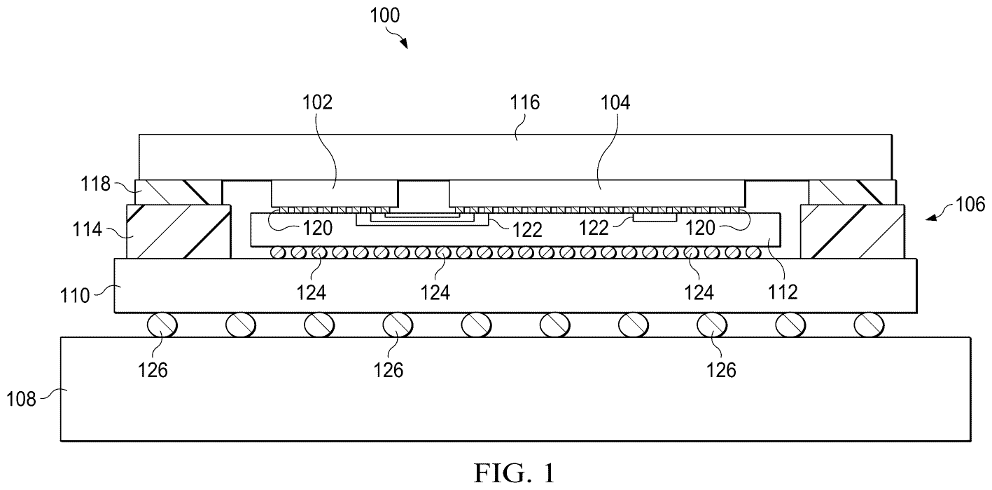

FIGS. 1 through 5, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, device packaging has become a primary focus of investment as electronic device manufacturers have embraced multi-chip/multi-core approaches from 2D to 2.5D and 3D in which die-to-die and die-to-package interconnectivity is a significant driver of performance. Interposers have become a common way to connect multiple dies, offering many data lanes with fine pitch and low loss. The newest interconnect standard, Universal Chiplet Interconnect Express (UCIe), requires decreased pitch and more complex signal routing, which cannot be provided using standard interposer designs.

This disclosure describes various semiconductor interposers with layer stackup features. As described in more detail below, a semiconductor interposer can be configured to be electrically coupled to one or more semiconductor devices. The interposer can include a core, a first stackup of layers over a first side of the core, and a second stackup of layers over a second side of the core opposite the first side. The core can include a substrate and first vias through the substrate. The first stackup of layers can include first redistribution layers and first dielectric layers. The first redistribution layers can be electrically coupled together using second vias through the first dielectric layers, and the first stackup of layers can form a first stripline and a second stripline. The second stackup of layers can include second redistribution layers and second dielectric layers. The second redistribution layers can be electrically coupled together using third vias through the second dielectric layers, and the second stackup of layers can form a third stripline.

In this way, silicon or other semiconductor interposers can support various features, such as through-silicon vias (TSVs), through-glass vias (TGVs), and/or multi-layer two-sided redistribution layers (RDLs). In some embodiments, these silicon or other semiconductor interposers can be used to support the UCIe interconnect standard. Also, in some embodiments, each of these silicon or other semiconductor interposers can be used to couple multiple dies together to form a multi-chip package (MCP), which may include one or more integrated circuits or chiplets (a sub-component or portion of an integrated circuit self-contained in a smaller chip size) and/or passive circuit components. In addition to or instead of coupling multiple dies together, each of these silicon or other semiconductor interposers can be used to couple one portion of a single die to another portion of the same die.

FIG. 1 illustrates an example of a semiconductor die package 100 according to this disclosure. More specifically, FIG. 1 illustrates a cross-sectional view of the semiconductor die package 100. As shown in FIG. 1, the semiconductor die package 100 includes one or more semiconductor dies 102-104. Each semiconductor die 102-104 represents any suitable semiconductor device, such as an integrated circuit chip containing any desired circuitry. In this example, there are two semiconductor dies 102-104 in the semiconductor die package 100. However, the semiconductor die package 100 may include a single semiconductor die or more than two semiconductor dies.

The one or more semiconductor dies 102-104 are incorporated into a package 106. The package 106 encases the semiconductor die(s) 102-104 and provides electrical connection to and from the semiconductor die(s) 102-104. In some cases, the package 106 provides electrical connection between the semiconductor die(s) 102-104 and a printed circuit board (PCB) 108. In this example, the package 106 includes a package substrate 110 and a semiconductor interposer 112. The package substrate 110 generally represents a structure that carries or supports other components of the package 106 and the semiconductor die(s) 102-104. The package substrate 110 may also include conductive pathways that can electrically couple the semiconductor interposer 112 to the PCB 108. The package substrate 110 may be formed from any suitable material(s) and in any suitable manner. For instance, the package substrate 110 may be fabricated using one or more dielectric materials and one or more metals or other conductive materials forming conductive pathways through the dielectric material(s).

The semiconductor interposer 112 generally represents a structure that electrically couples one or more semiconductor dies 102-104 to the package substrate 110 and/or that electrically couples two or more semiconductor dies 102-104 to each other and/or that electrically couples a portion of a single semiconductor die 102-104 to another portion of the same semiconductor die 102-104. As described below, the semiconductor interposer 112 represents a multi-layer semiconductor interposer that is capable of transporting signals to and/or from one or more semiconductor dies 102-104. The semiconductor interposer 112 may be formed from any suitable material(s) and in any suitable manner. For instance, the semiconductor interposer 112 may be fabricated using one or more dielectric materials and one or more metals or other conductive materials forming conductive pathways through the dielectric material(s).

The package 106 in this example also includes a stiffener 114 and a lid 116. The stiffener 114 is mounted on the package substrate 110 and provides structural support for the package 106. In some cases, the stiffener 114 may represent a square or rectangular ring or other component that surrounds the semiconductor interposer 112. Note that because FIG. 1 illustrates a cross-sectional view of the semiconductor die package 100, sections of such a stiffener 114 appear on opposite sides of the semiconductor interposer 112. However, the stiffener 114 may have any other suitable form, such as separate components that collectively provide structural support for the package 106. The stiffener 114 may be formed from any suitable material(s) and in any suitable manner. For instance, the stiffener 114 may be fabricated using one or more metals, plastics, or other materials that provide structural reinforcement.

The lid 116 is positioned over the semiconductor die(s) 102-104 and the semiconductor interposer 112 and encases the semiconductor die(s) 102-104 and the semiconductor interposer 112 within an interior space of the package 106. The lid 116 may be formed from any suitable material(s) and in any suitable manner. For instance, the lid 116 may be fabricated using one or more metals or other materials having high thermal conductivity. In some cases, the one or more semiconductor dies 102-104 may be thermally coupled to the lid 116, such as via direct contact or via a thermal interface material. This allows the lid 116 to help remove thermal energy from the package 106. The lid 116 may be secured in place in any suitable manner, such as via an adhesive or other bonding material 118 that couples the lid 116 to the stiffener 114.

The PCB 108 represents a substrate having electrical pathways facilitating the transport of electrical signals to and from the package 106. For example, the PCB 108 may include a substrate and conductive traces formed on one or both major surfaces of the substrate, optionally along with vias or other conductive pathways through the substrate. Among other things, the PCB 108 can often be used to provide power to the semiconductor die(s) 102-104 within the package 106 and to provide data signals to and receive data signals from the semiconductor die(s) 102-104. The PCB 108 may be formed from any suitable material(s) and in any suitable manner. For instance, the PCB 108 may be formed primarily using one or more dielectric materials, and one or more metals or other conductive materials may be used to form traces and other conductive pathways of the PCB 108.

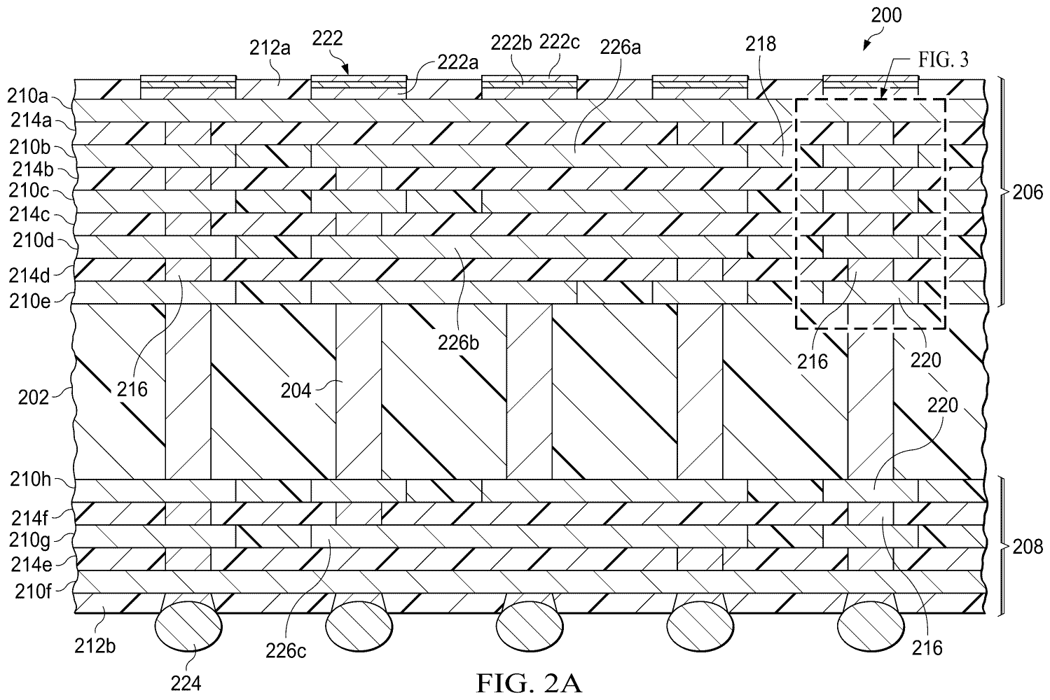

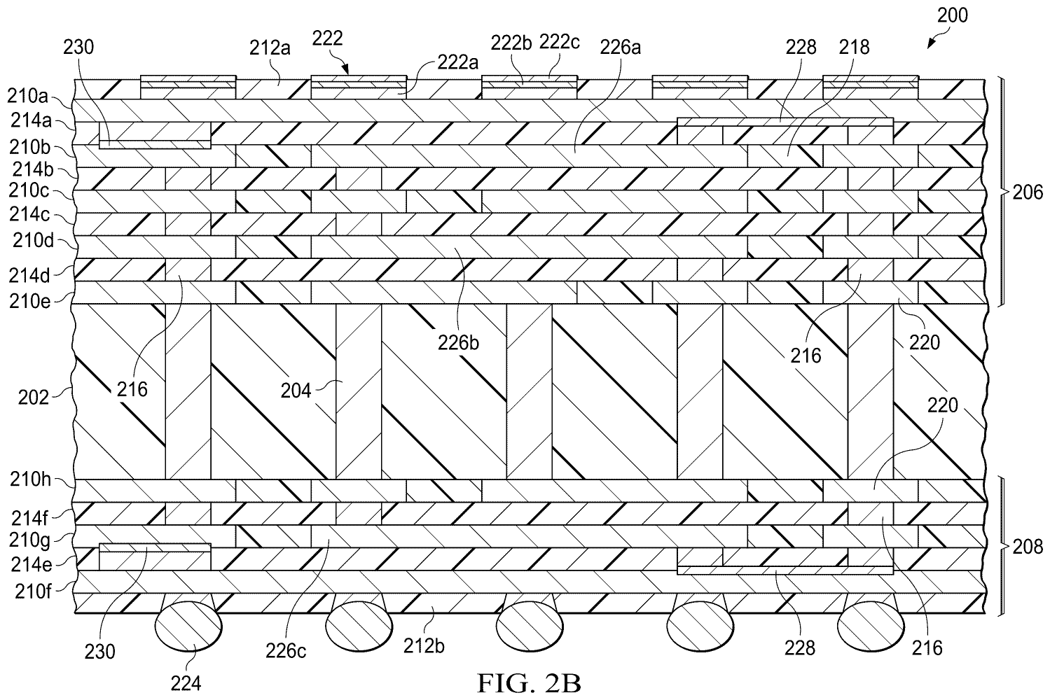

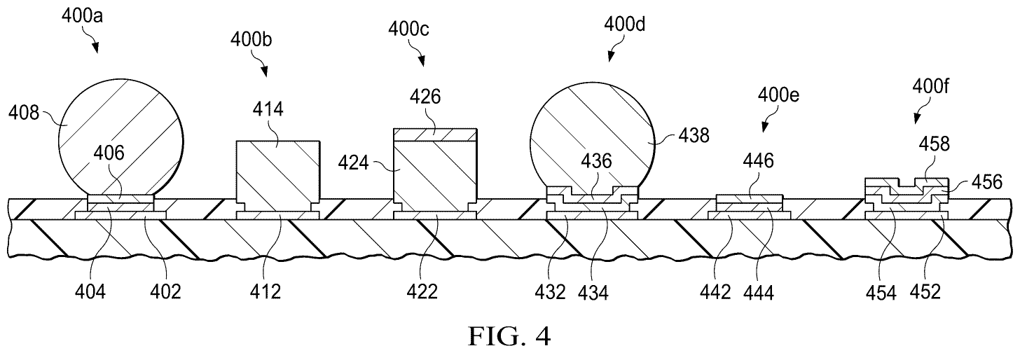

Various electrical connectors are used in FIG. 1 to support electrical connection between components. For example, an array of electrical connectors 120 can be used to electrically couple the semiconductor die(s) 102-104 and the semiconductor interposer 112. The semiconductor interposer 112 can include an array of electrical connectors 122 that can be used to electrically couple a particular electrical connector 120 for one semiconductor die 102-104 to a particular electrical connector 120 for the same or another semiconductor die 102-104. An array of electrical connectors 124 can be used to electrically couple the semiconductor interposer 112 and the package substrate 110. An array of electrical connectors 126 can be used to electrically couple the package substrate 110 and the PCB 108. Each connector 120-126 can have any suitable form and include any suitable conductive material(s). Example forms for the connectors 120, 124 are shown in FIG. 4, which is described below. However, the connectors 120, 124 may have any other suitable form. In some cases, the connectors 122 can be formed using layers within the interposer 112, which are described in more detail below in connection with FIGS. 2A and 2B. In some cases, the connectors 126 may represent ball grid arrays (BGAs), column grid arrays (CGAs), or other collections of electrical connectors. However, the connectors 126 may have any other suitable form.

As described in further detail below, the semiconductor interposer 112 supports a number of novel features to provide improved interconnection in the package 106 or other system. For example, the semiconductor interposer 112 provides a high-density interconnect that can be used at high frequencies (such as radio frequencies, for example) and that has an improved configuration for design performance of the circuit conductors. Moreover, the semiconductor interposer 112 provides a novel stackup of layers and features that enable improved or optimized routing to connect with semiconductor die(s) 102-104 having high-frequency signal requirements. For example, the semiconductor interposer 112 can include a high density device that enables digital routing for semiconductor die(s) 102-104 implementing digital protocols, such as advanced interface bus (AIB), UCIe, or the like.

Although FIG. 1 illustrates one example of a semiconductor die package 100, various changes may be made to FIG. 1. For example, the specific semiconductor die package 100 shown here is for illustration and explanation only. Die packages can come in a wide variety of configurations, and FIG. 1 is merely meant to illustrate one example of a die package in which a semiconductor interposer 112 may be used. The semiconductor interposer 112 may be used in any other suitable manner.

FIGS. 2A and 2B illustrate examples of semiconductor interposers 200 with layer stackup features according to this disclosure. More specifically, FIGS. 2A and 2B illustrate cross-sectional views of two examples of an interposer 200. For ease of explanation, the interposers 200 shown in FIGS. 2A and 2B are described as being used as the semiconductor interposer 112 in the semiconductor die package 100 shown in FIG. 1. However, the interposers 200 shown in FIGS. 2A and 2B may be used in any other suitable manner.

As shown in FIG. 2A, the interposer 200 includes a substrate 202 and conductive vias 204 through the substrate 202. The substrate 202 can be formed from any suitable material(s) and in any suitable manner. In some embodiments, the substrate 202 can be formed using silicon. The vias 204 can also be formed from any suitable material(s) and in any suitable manner. In some embodiments, the vias 204 can be formed by drilling or otherwise forming holes through the substrate 202 and depositing one or more conductive materials, such as copper or other metal(s), in the holes. Note that when the substrate 202 represents a silicon substrate, the vias 204 may sometimes be referred to as through-silicon vias (TSVs). As can be seen here, each of the vias 204 can have a height that is significantly larger than its width, causing these vias 204 to have a relatively large aspect ratio. For instance, the substrate 202 may have a thickness (height) of between about 100 microns to about 500 microns, such as a thickness of about 200 microns. Each of the vias 204 may have a diameter of about 20 microns, so the vias 204 could have an aspect ratio of about 5:1 to about 25:1. Note, however, that the vias 204 may have any suitable diameter, such as about 2 microns to about 20 microns.

The interposer 200 also includes a stackup 206 of layers on one side of the substrate 202 and a stackup 208 of layers on the opposing side of the substrate 202. The stackup 206 includes multiple redistribution layers (RDLs) 210a-210e, as well as an organic dielectric layer 212a and multiple inorganic dielectric layers 214a-d. Conductive vias 216 through the inorganic dielectric layers 214a-214d electrically couple the redistribution layers 210a-210e to one another. In addition, the redistribution layer 210a is electrically coupled to electrical connectors 222 formed through the organic dielectric layer 212a. The electrical connectors 222 may represent the electrical connectors 120, 124 or may be electrically coupled to the electrical connectors 120, 124. In the illustrated example, there are five redistribution layers 210a-210e, one organic dielectric layer 212a, and four inorganic dielectric layers 214a-214d, although other numbers of redistribution layers and dielectric layers may be used.

The redistribution layers 210a-210e include conductive pathways that route electrical signals between desired locations. Each redistribution layer 210a-210e may be formed from any suitable material(s) and in any suitable manner. For instance, each redistribution layer 210a-210e may be fabricated using one or more dielectric materials and one or more metals or other conductive materials forming conductive pathways through the dielectric material(s). As a particular example, each redistribution layer 210a-210e may include copper conductive pathways formed in benzocyclobutene (BCB), which can represent a low-loss dielectric material. Thus, as described in more detail below, at least some of the redistribution layers 210b-210e can include dielectric portions 218 configured to allow conductive paths, such as transmission lines, to be formed in the stackup 206 from multiple redistribution layers 210a-210e.

In some cases, conductive traces in each of the redistribution layers 210a-210e may have a minimum line width of about 2 microns and a minimum line spacing of about 2 microns (although smaller or larger distances can be used). The dielectric layers 212a and 214a-214e separate the redistribution layers 210a-210e from each other and from other components of the interposer 200. Each dielectric layer 212a and 214a-212e may be formed from any suitable dielectric material(s) and in any suitable manner. For instance, for a particular example, the organic dielectric layer 212a may be fabricated using BCB, and the inorganic dielectric layers 214a-214e may be fabricated using silicon dioxide (SiO₂). The inorganic dielectric layers 214a-214e may also be fabricated using a blend of dielectric materials, including SiO₂, silicon nitride (Si₃N₄), aluminum nitride (AlN), and/or the like. In some cases, the inorganic dielectric layers 214a-214e may include material(s) having dielectric constants between about 1 and about 12.

The vias 216 may be formed from any suitable conductive material(s) and in any suitable manner. For example, each via 216 may be fabricated using copper or other metal(s). some cases, each of the vias 216 may be cylindrical, or each of the vias 216 may have a “cup” shape in which (i) a bottom of the via 216 is somewhat smaller in diameter than a top of the via 216 and (ii) sides of the via 216 are curved outward. As particular examples, the vias 216 could be formed using copper damascene or other processes, and the vias 216 can have or be coupled to suitable pads like single-or dual-damascene pads.

The vias 216 can be formed in the inorganic dielectric layers 214a-214d above and/or below the redistribution layers 210a-210e. In some cases, each of the vias 216 may have a diameter of about 1 micron to about 4 microns. Conductive portions 220 of the redistribution layers 210a-210e below each of the vias 216 may have a diameter of about 2 microns to about 5 microns, with the conductive portions 220 having a diameter larger than the diameter of the vias 216. For instance, in a particular case, each of the vias 216 may have a diameter of about 3 microns, and each of the conductive portions 220 may have a diameter of about 4 microns. However, the vias 216 and the conductive portions 220 of the redistribution layers 210a-210e contacting the vias 216 may each have any other suitable dimensions.

The electrical connectors 222 represent any suitable structures configured to provide electrical connection to the interposer 200. The electrical connectors 222 can be formed using any suitable conductive material(s) and in any suitable manner. In some embodiments, the electrical connectors 222 may be defined by any combination of the following features: a passivation layer (one or more organic or inorganic materials), a solder-mask material, an under-bump metallurgy (such as nickel and gold or copper and nickel), a solder material, and a copper or other pillar or bump plating (which in some cases could range from an about 10 micron pitch to an about 1 millimeter pitch). In this example, each of the electrical connectors 222 represents a multi-layer arrangement of conductive layers. In this particular example, each of the electrical connectors 222 includes three conductive layers, such as a layer 222a of copper, a layer 222b of nickel, and a layer 222c of gold. However, the electrical connectors 222 may have any other suitable structure. Specific examples of different forms of the electrical connectors 222 are shown in FIG. 4, which is described below.

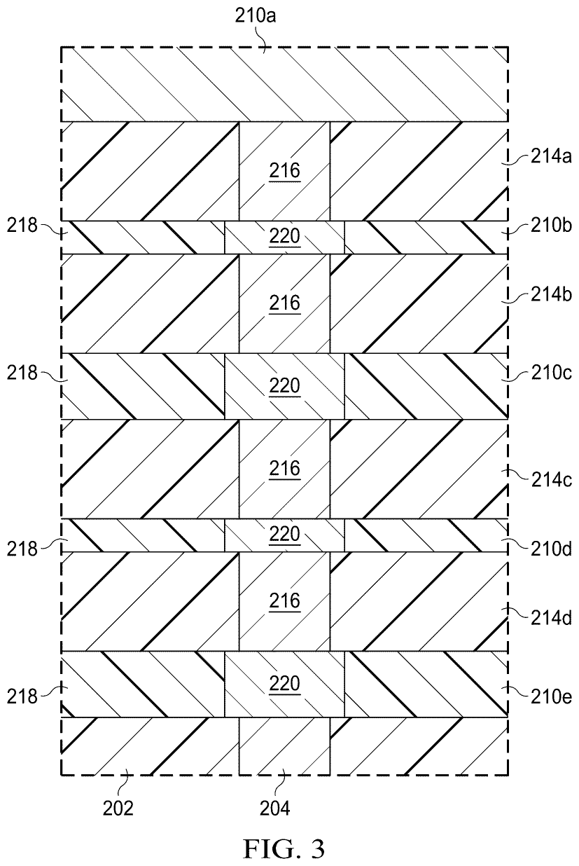

As can be seen here, the stackup 206 represents a multi-layer stack of materials having multiple redistribution layers 210a-210e and multiple dielectric layers 212a and 214a-214d. In some cases, each of the redistribution layers 210a-210e and the inorganic dielectric layers 214a-214d may have substantially the same thicknesses. In other cases, as shown in FIG. 3, each of the inorganic dielectric layers 214a-214d may be thicker than the redistribution layers 210a-210e. In addition, the redistribution layers 210a-210e and the inorganic dielectric layers 214a-214d can have thicknesses in a specified pattern. For example, the specified pattern can include a 2-3-1-3-2 pattern, where the redistribution layers 210a-210e may have thicknesses that alternate between a thickness (height) of about twice a base value (2×) and the base value (1×) as compared to the inorganic dielectric layers 214a-214d, which may each have a thickness (height) of about three times the base value (3×). Thus, for a particular example in which the base value, x, is 1 micron, the redistribution layers 210a-210e may have thicknesses that alternate between a thickness of about 2 microns and about 1 micron. For this particular example, the redistribution layers 210a, 210c, and 210e may each have a thickness of about 2 microns, and the redistribution layers 210b and 210d may each have a thickness of about 1 micron. In addition, for this particular example, each of the inorganic dielectric layers 214a-214d may have a thickness of about 3 microns. In other cases using the 2-3-1-3-2 pattern, the base value may be any suitable thickness other than 1 micron, while the relative thicknesses of the redistribution layers 210a-210e and the inorganic dielectric layers 214a-214d may still be proportional to each other following the same pattern. To provide feature sizes that allow the high density desired for implementing digital protocols, the base value can be between about 0.5 microns and about 2 microns.

Note that the stackups 206-208 here are nearly symmetrical, meaning the stackup 208 is close to a mirror image of the stackup 206, or has a similar design as the stackup 206, except with fewer layers. As a result, the same elements described above with respect to the stackup 206 can be used in the stackup 208. For example, the stackup 208 can include an organic dielectric layer 212b, multiple redistribution layers 210f-210h, and multiple inorganic dielectric layers 214e-f. However, the stackup 208 can include three redistribution layers 210f-210h instead of the five layers 210a-210e in the stackup 206, and two inorganic dielectric layers 214e-f instead of the four layers 214a-214d included in the stackup 206. The stackup 208 can also include vias 216, conductive portions 220 of the redistribution layers 210f-210h contacting the vias 216, and electrical connectors 224. In some cases, the electrical connectors 224 can represent BGAs, CGAs, or other types of electrical connectors that are the same as or different from the electrical connectors 222 included in the stackup 206.

The entire interposer 200 itself may have any suitable size, shape, and dimensions. For example, in some cases, the interposer 200 may represent a relatively small device, such as a device having dimensions of about 1 millimeter by about 1 millimeter. In other cases, the interposer 200 may represent a relatively large device, such as a circular device having a diameter of about 300 millimeters. In general, the size, shape, and dimensions of the interposer 200 can vary based on a number of factors, such as the intended application and the fabrication process used.

As shown in FIGS. 2A and 2B, the vias 204, vias 216, and conductive portions 220 of the redistribution layers 210a-210e can be stacked on top of one another. In some cases, this allows for the creation of direct electrical pathways to be formed straight through the interposer 200. This can enable the creation of fully-stacked vias through the interposer 200 from electrical connectors 222 on top of the interposer 200 to electrical connectors 224 on bottom of the interposer 200. In those cases, there may effectively be straight-through vias through the interposer 200 having no jogs.

In some embodiments, the stackups 206-208 can be used to form transmission or impedance lines using sub-groups of copper or other conductive layers (such as five redistribution layers 210a-210e) and inorganic dielectric layers (such as four dielectric layers 214a-214d). The conductive layers may represent alternating signal and ground layers (such as a pattern of ground-signal-ground-signal-ground when five redistribution layers 210a-210e are used) to provide shielded high-speed RF signal lines. For the dimensions described in the above example in which the redistribution layers 210a-210e and the inorganic dielectric layers 214a-214d have thicknesses in a 2-3-1-3-2 pattern, this could provide a stackup 206 that provides two transmission lines 226a-226b having an impedance of about 50 Ohms and a stackup 208 that provides a single transmission line 226c having an impedance of about 50 Ohms. In some cases, the transmission lines 226a-226c can have a width of about 2 microns. However, the transmission lines 226a-226c can have any other suitable width enabling high-density digital signaling. In particular embodiments, the transmission lines 226a-226c may have an effective dielectric constant in the range of about 3.5 to about 4.5.

In the example described above, the substrate 202 and vias 204 could represent a core having 50-Ohm (or other) impedance lines above and below the core. The core itself could incorporate a shielded coaxial connection (such as one having an impedance of about 50 Ohms) containing a set of TSVs or other vias 204, and the vias 204 may include a center via and two or more ground vias passing through the core. In some cases, the stackups 206-208 may form multiple (such as two or more) separate stripline shielded structures, which can be stacked or crossed-over without interference.

For instance, in the stackup 206, two striplines may include nine layers (210a-210e and 214a-214d), with a first stripline including layers 210a-210c (in a ground-signal-ground pattern) and 214a-214b, and a second stripline including layers 210c-210e (in a ground-signal-ground pattern) and 214c-214d. In this way, the first and second striplines may share a common ground formed in the layer 210c, with the transmission line 226a formed in the center layer 210b of the first stripline and the transmission line 226b formed in the center layer 210d of the second stripline. In the stackup 208, a third stripline may include five layers 210f-210h (in a ground-signal-ground pattern) and 214e-214f. Thus, the transmission line 226c may be formed in the center layer 210g of the third stripline. In other embodiments, the same type of geometry may be used but modified to create a combination of controlled transmission or impedance lines having differential pairs with controlled impedances (such as about 100 Ohms and about 25 Ohms). In these embodiments, the substrate 202 and vias 204 could represent a differential coaxial pathway through the core of the interposer 200. Thus, in some cases, the transmission line 226a and the transmission 226b can each form a single-ended transmission line. In other cases, the transmission line 226a and the transmission line 226b can together form a differential transmission line.

The various components of the interposer 200 may be fabricated in any suitable manner. For example, in some embodiments, the conductive traces and vias in the layers 210a-210e, 212a and 214a-214d may be fabricated using electroplating, an etch-back process, and/or a damascene patterning processes. As particular examples, patterns in dielectric material(s) may be photo-defined or etched using photoresist or hard mask layers as an etch mask. As other particular examples, dielectric material(s) may be coated after conductive components in each of the layers 210a-210e, 212a, and 214a-214d have been patterned, and chemical-mechanical polishing (CMP) or other etch-back processes can be used to reveal electrical contact regions prior to patterning subsequent conductor patterns.

The interposer 200 can provide a novel stackup of layers and features that enable improved or optimized routing to connect with semiconductor die(s) 102-104 having high-frequency signal requirements. For example, because the distance between semiconductor die(s) 102-104 and/or between connectors 122 on a single semiconductor die 102-104 can be very short and the number of signals between the dies(s) 102-104 and/or the connectors 122 can be very high, implementing extremely small feature sizes for the interposer 200 allows a high density to be achieved. This high-density interposer 200 can enable digital routing for semiconductor die(s) 102-104 implementing digital protocols, such as AIB, UCIe, or the like, in addition to enabling routing for any other suitable communication protocols.

As shown in FIG. 2B, the stackups 206-208 may optionally include one or more embedded passive components. As an example, one or more resistors 228 may be embedded in the stackups 206-208. Each resistor 228 may have any suitable resistance and can be included on or in any layer(s) between electrical conductors. Each resistor 228 may be planar or non-planar. Each resistor 228 may be formed using any suitable material(s), such as tantalum (Ta), tantalum nitride (TaN), or titanium nitride (TiN). In some cases, each resistor 228 may be fabricated using a thin film. Also, in some cases, each resistor 228 may have a sheet resistance value between about 1 and about 1,000 Ohms/square. As a particular example, each resistor 228 may have a target value of about 25 Ohms/square to about 50 Ohms/square.

As another example, one or more capacitors 230 may be embedded in the stackups 206-208. Each capacitor 230 may have any suitable capacitance and can be included on or in any layer(s) between electrical conductors. In some cases, each capacitor 230 may be positioned on or within a redistribution layer 210a-210e or 210f-210h. Each capacitor 230 may have any suitable design, such as a metal-insulator-metal (MIM) design. When using an MIM design, two conductive layers (such as layers of copper or other metal(s)) can be separated by a dielectric insulator. In some embodiments, the dielectric insulator may represent SiO₂, Si₃N₄, AlN, titanium dioxide (TiO₂), or hafnium oxide (HfO₂). In some cases, each capacitor 230 may have a target value of about 10 pF to about 10 nF. As a particular example, each capacitor 230 may have a target value of about 100 pF/mm² to about 1,000 pF/mm². Also, in some cases, each capacitor 230 may include a dielectric material having a dielectric constant between about 1 and about 100.

In some embodiments, each resistor 228 may be formed as a thin-film resistor, which in some cases may be fabricated by performing a subtractive etch-back or lift-off patterning process using materials such as Ta, TaN, and/or TiN. Also, in some embodiments, each capacitor 230 may be formed in a metal-insulator-metal configuration using thin films, such as one in which the insulator is SiO₂, Si₃N₄, AlN, TiO₂, and/or HfO₂. In other embodiments, each capacitor 230 may be fabricated using etched silicon or other features, such as vias or trenches, that increase surface area and therefore capacitance per unit of area on the interposer 200.

Although FIGS. 2A and 2B illustrate two examples of a semiconductor interposer 200 with layer stackup features, various changes may be made to FIGS. 2A and 2B. For example, the sizes, shapes, dimensions, and materials described above for the various components of the interposer 200 can easily vary depending on the circumstances. In addition, the numbers and placements of any included resistors 228 and/or capacitors 230 can easily vary depending on the circumstances.

FIG. 3 illustrates a cross-sectional view of an example of a portion of a semiconductor interposer with layer stackup features according to this disclosure. For ease of explanation, the portion of an interposer 200 shown in FIG. 3 is described as being a portion of the interposer 200 shown in FIG. 2A.

As shown in FIG. 3, the redistribution layers 210a-210e and the inorganic dielectric layers 214a-214d have relative thicknesses in a 2-3-1-3-2 pattern, as described above in connection with FIGS. 2A and 2B. Thus, as shown, the redistribution layer 210a, the vias 216, and the conductive portions 220 contacting the vias 216 also have relative thicknesses in a 2-3-1-3-2 pattern. In a particular example, redistribution layers 210a, 210c, and 210e may each have a thickness of about 2 microns, the redistribution layers 210b and 210d may each have a thickness of about 1 micron, and each of the inorganic dielectric layers 214a-214d may have a thickness of about 3 microns.

Note that the vias 216 and the conductive portions 220 of the redistribution layers 210b-210e contacting the vias 216 here may have any suitable dimensions. In some cases, for instance, as shown in FIG. 3, the vias 216 may each have a diameter of about 3 microns, and the conductive portions 220 of the redistribution layers 210b-210e may each have a diameter of about 4 microns, which makes the conductive portions 220 of the redistribution layers 210b-210e only slightly wider than the vias 216. However, the conductive portions 220 of the redistribution layers 210b-210e contacting the vias 216 may have any other suitable dimensions wider than the vias 216.

Although FIG. 3 illustrates a cross-sectional view of one example of a portion of a semiconductor interposer 200 with layer stackup features, various changes may be made to FIG. 3. For example, while following a specified pattern of relative thicknesses, the numbers and sizes of the various layers 210a-210e and 214a-214d of the interposer 200 can easily vary depending on the circumstances.

FIG. 4 illustrates examples of connection options 400a-400f for a semiconductor interposer with layer stackup features according to this disclosure. For example, the connection options 400a-400f here may represent different forms of the electrical connectors 222 and/or 224 described above. However, the connection options 400a-400f shown in FIG. 4 may be used in any other interposer.

As shown in FIG. 4, the connection option 400a includes a stack of layers 402-406 and a solder bump 408. The stack of layers 402-406 can include any suitable conductive material(s), such as a layer 402 of copper, a layer 404 of nickel, and a layer 406 of gold. In some embodiments, the stack of layers 402-406 can be formed using an electroless nickel immersion gold (ENIG) process in which (i) nickel is formed using electroless nickel plating and (ii) the nickel is covered with gold during immersion in a gold-containing solution. The solder bump 408 can also include any suitable conductive material(s), such as tin-lead (SnPb) solder alloy, tin-silver (SnAg) solder alloy, or tin-silver-copper (SAC) solder alloy. The solder bump 408 may have any suitable size, shape, and dimensions, such as a diameter of about 60 microns to about 250 microns. Multiple instances of the connection option 400a may have solder bumps 408 with any suitable spacing(s), such as a pitch of about 100 microns to about 1,000 microns.

The connection option 400b includes a base layer 412 and a pillar 414. The base layer 412 can include any suitable conductive material(s), such as a layer of copper. The pillar 414 can also include any suitable conductive material(s), such as one or more layers of copper. The pillar 414 may be formed in any suitable manner, such as via electroplating. The pillar 414 may have any suitable size, shape, and dimensions. In some cases, the pillar 414 may have a diameter of about 10 microns to about 80 microns. Multiple instances of the connection option 400b may have pillars 414 with any suitable spacing(s), such as a pitch of about 22 microns to about 150 microns.

The connection option 400c is similar to the connection option 400b and includes a base layer 422 and a pillar 424, as well as a solder cap 426. The base layer 422 and the pillar 424 may be the same as or similar to the base layer 412 and the pillar 414. The solder cap 426 can be formed over the pillar 424 in any suitable manner. The solder cap 426 can also include any suitable conductive material(s), such as SnPb solder alloy, SnAg solder alloy, or tin (Sn) solder.

The connection option 400d includes a stack of layers 432-436 and a solder bump 438. The stack of layers 432-436 can include any suitable conductive material(s), such as a layer 432 of copper, another layer 434 of copper (such as an electroplated layer), and a layer 436 of nickel (such as an electroplated layer). The solder bump 438 can also include any suitable conductive material(s), such as SnPb, SnAg, or SAC solder alloy. The solder bump 438 may have any suitable size, shape, and dimensions, such as a diameter of about 60 microns to about 250 microns. Multiple instances of the connection option 400d may have solder bumps 438 with any suitable spacing(s), such as a pitch of about 100 microns to about 1,000 microns.

The connection option 400e includes a stack of layers 442-446 that are generally planarized to have a top surface at or near the surface of the surrounding dielectric. The stack of layers 442-446 can include any suitable conductive material(s), such as a layer 442 of copper, a layer 444 of nickel and optionally palladium, and a layer 446 of gold. Similarly, the connection option 400f includes a stack of layers 452-458, but the layers 454-458 in this example are nonplanar. The stack of layers 452-458 can include any suitable conductive material(s), such as a layer 452 of copper, another layer 454 of copper, a layer 456 of nickel and optionally palladium, and a layer 458 of gold. In some embodiments, the stacks in the connection options 400e-400f may be fabricated using an ENIG process or an electroless nickel electroless palladium immersion gold (ENEPIG) process. In some embodiments, the connection options 400e-400f may represent probe or wire bond pads.

Although FIG. 4 illustrates examples of connection options 400a-400f for a semiconductor interposer with layer stackup features, various changes may be made to FIG. 4. For example, the connection options 400a-400f shown here are examples only, and other forms may be used for the electrical connectors 222 and/or 224 or other electrical connectors in the semiconductor interposer 200. Also, the connection options 400a-400f here illustrate that there are a wide variety of options available for use on both the top and bottom surfaces of the semiconductor interposer 200. Any one or any combination of the connection options 400a-400f and/or other connection options may be used with any given implementation of a semiconductor interposer and tailored to the specific design specifications for that semiconductor interposer.

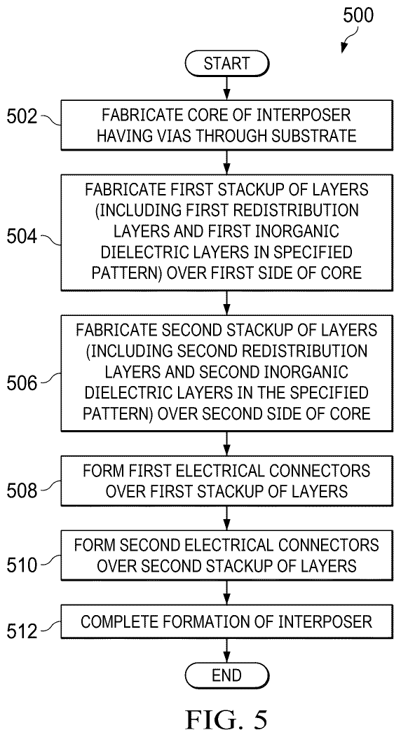

FIG. 5 illustrates an example of a method 500 for forming a semiconductor interposer with layer stackup features according to this disclosure. For ease of explanation, the method 500 shown in FIG. 5 is described as being used to form the interposer 200 shown in FIG. 2A or 2B, which may be used as the semiconductor interposer 112 in the semiconductor die package 100 shown in FIG. 1. However, the method 500 shown in FIG. 5 may be used to form any other suitable semiconductor interposer, and the semiconductor interposer may be used in any other suitable manner.

As shown in FIG. 5, a core of an interposer is fabricated at step 502. This may include, for example, obtaining a silicon or other substrate 202 and forming TSVs or other vias 204 through the substrate 202. A first stackup of layers is formed over a first side of the core at step 504. This may include, for example, forming a first stackup 206 of layers that includes first redistribution layers 210a-210e, first organic dielectric layer 212a, and first inorganic dielectric layers 214a-214d over a first side of the substrate 202. The first redistribution layers 210a-210e and the first inorganic dielectric layers 214a-214d can be formed having relative thicknesses in a specified pattern (such as a 2-3-1-3-2 pattern, for example). In a particular example, the first redistribution layers 210a, 210c, and 210e can be formed having a thickness of about twice a base value, the first redistribution layers 210b and 210d can be formed having a thickness of about the base value, and the first inorganic dielectric layers 214a-214d can be formed having a thickness of about three times the base value, where the base value can be between about 0.5 microns and 2 microns. The first redistribution layers 210a-210e can be formed to include any desired conductive pathways to route electrical signals. Vias 216 can be formed to pass electrical signals between the first redistribution layers 210a-210e through the first inorganic dielectric layers 214a-214d. The first inorganic dielectric layers 214a-214d are thicker than the first redistribution layers 210a-210e to provide reduced loss when RF signals propagate through the first stackup 206 of layers. Optionally, one or more embedded passive components (such as one or more resistors 228 and/or one or more capacitors 230) may be formed within the first stackup 206 of layers.

A second stackup of layers is formed over a second side of the core at step 506. This may include, for example, forming a second stackup 208 of layers that includes second redistribution layers 210f-210h, second organic dielectric layer 212b, and second inorganic dielectric layers 214e-214f over a second side of the substrate 202. The second redistribution layers 210f-210h and the second inorganic dielectric layers 214e-214f can be formed having relative thicknesses in the specified pattern (such as the 2-3-1-3-2 pattern, for example). In a particular example, the second redistribution layers 210f and 210h can be formed having a thickness of about twice the base value, the second redistribution layer 210g can be formed having a thickness of about the base value, and the second inorganic dielectric layers 214e-214f can be formed having a thickness of about three times the base value. The second redistribution layers 210f-210h can be formed to include any desired conductive pathways to route electrical signals. Vias 216 can be formed to pass electrical signals between the second redistribution layers 210f-210h through the second inorganic dielectric layers 214e-214f. The second inorganic dielectric layers 214e-214f are thicker than the second redistribution layers 210f-210h to provide reduced loss when RF signals propagate through the second stackup 208 of layers. Optionally, one or more embedded passive components (such as one or more resistors 228 and/or one or more capacitors 230) may be formed within the second stackup 208 of layers. In some cases, the second stackup 208 of layers may have a similar design as the first stackup 206 of layers, such as when the second stackup 208 of layers is similar to a mirror image of the first stackup 206 of layers but having fewer layers 210 and 214.

First electrical connectors are formed over the first stackup of layers at step 508, and second electrical connectors are formed over the second stackup of layers at step 510. This may include, for example, forming first electrical connectors 222 over the first stackup 206 of layers and forming second electrical connectors 224 over the second stackup 208 of layers. Each electrical connector 222 and/or 224 may have any suitable form, such as any of the connection options 400a-400f shown in FIG. 4. Also, electrical connectors 222 and electrical connectors 224 may each include different forms, such as two or more of the connection options 400a-400f shown in FIG. 4. Fabrication of the interposer is completed at step 512. This may include, for example, completing any additional processing steps needed to form a complete semiconductor interposer 200.

In this way, a high-density interposer 200 can be provided that includes a novel stackup of layers and features that are sized to enable improved or optimized routing to connect with semiconductor die(s) 102-104 having high-frequency signal requirements. For example, because the distance between semiconductor die(s) 102-104 and/or between connectors 122 on a single semiconductor die 102-104 can be very short and the number of signals between the dies(s) 102-104 and/or the connectors 122 can be very high, implementing extremely small feature sizes for the interposer 200 allows a high density to be achieved. This high-density interposer 200 can enable digital routing for semiconductor die(s) 102-104 implementing digital protocols, such as AIB, UCIe, or the like, in addition to enabling routing for any other suitable communication protocols.

Although FIG. 5 illustrates one example of a method 500 for forming a semiconductor interposer with layer stackup features, various changes may be made to FIG. 5. For example, while shown as a series of steps, various steps in FIG. 5 may overlap, occur in parallel, occur in a different order, or occur any number of times (including zero times).

It may be advantageous to set forth definitions of certain words and phrases used throughout this patent document. The term “about” (when used with a numerical value) indicates that the numerical value may vary by up to ±10%. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
an interposer configured to be electrically coupled to one or more semiconductor devices, the interposer comprising:
a core comprising a substrate and first vias through the substrate;
a first stackup of layers over a first side of the core, the first stackup of layers comprising first redistribution layers and first dielectric layers, the first redistribution layers electrically coupled together using second vias through the first dielectric layers, the first stackup of layers forming a first stripline and a second stripline; and
a second stackup of layers over a second side of the core opposite the first side, the second stackup of layers comprising second redistribution layers and second dielectric layers, the second redistribution layers electrically coupled together using third vias through the second dielectric layers, the second stackup of layers forming a third stripline.

2. The apparatus of claim 1, wherein:
at least some of the first, second, and third vias are stacked to form direct electrical pathways straight through the interposer;
the first dielectric layers are thicker than the first redistribution layers;
the second dielectric layers are thicker than the second redistribution layers; and
each of the first dielectric layers and the second dielectric layers comprises a material having a dielectric constant between about 1 and about 12.

3. The apparatus of claim 1, wherein:
the first stackup of layers comprises at least five first redistribution layers separated by at least four first dielectric layers; and
the second stackup of layers comprises at least three second redistribution layers separated by at least two second dielectric layers.

4. The apparatus of claim 1, wherein:
the first redistribution layers alternate between having a thickness of about twice a base value and about the base value;
each of the first dielectric layers has a thickness of about three times the base value;
the second redistribution layers alternate between having a thickness of about twice the base value and about the base value; and
each of the second dielectric layers has a thickness of about three times the base value.

5. The apparatus of claim 4, wherein the base value is between about 0.5 microns and about 2 microns.

6. The apparatus of claim 5, wherein:
the base value is about 1 micron;
each of the second vias and the third vias comprises a diameter of about 3 microns; and
each of a plurality of conductive portions of the first redistribution layers contacting the second vias and each of a plurality of conductive portions of the second redistribution layers contacting the third vias comprises a diameter of about 4 microns.

7. The apparatus of claim 1, wherein each stackup of layers further comprises at least one of: one or more embedded resistors, each having a sheet resistance value between about 1 and about 1,000 Ohms/square, or one or more embedded capacitors, each comprising a dielectric material having a dielectric constant between about 1 and about 100.

8. The apparatus of claim 1, wherein the interposer further comprises:
first electrical connectors over and electrically coupled to the first stackup of layers; and
second electrical connectors over and electrically coupled to the second stackup of layers.

9. The apparatus of claim 1, wherein:
the first stripline forms a first transmission or impedance line;
the second stripline forms a second transmission or impedance line;
the third stripline forms a third transmission or impedance line; and
each of the first, second, and third transmission or impedance lines has a specified impedance.

10. The apparatus of claim 9, wherein:
each of the first stripline and the second stripline forms a single-ended transmission line; or
the first stripline and the second stripline together form a differential transmission line.

11. The apparatus of claim 1, wherein each stackup of layers comprises a high-density stackup of layers configured to implement a digital communication protocol between at least one of: two or more semiconductor devices or portions of a single semiconductor device.

12. The apparatus of claim 1, wherein:
the first redistribution layers have a ground-signal-ground-signal-ground pattern such that the first stripline and the second stripline share a common ground; and
the second redistribution layers have a ground-signal-ground pattern.

13. A system comprising:
one or more semiconductor devices; and
a package enclosing the one or more semiconductor devices, the package comprising an interposer electrically coupled to the one or more semiconductor devices, the interposer comprising:
a core comprising a substrate and first vias through the substrate;
a first stackup of layers over a first side of the core, the first stackup of layers comprising first redistribution layers and first dielectric layers, the first redistribution layers electrically coupled together using second vias through the first dielectric layers, the first stackup of layers forming a first stripline and a second stripline; and
a second stackup of layers over a second side of the core opposite the first side, the second stackup of layers comprising second redistribution layers and second dielectric layers, the second redistribution layers electrically coupled together using third vias through the second dielectric layers, the second stackup of layers forming a third stripline.

14. The system of claim 13, wherein:
the first redistribution layers alternate between having a thickness of about twice a base value and about the base value;
each of the first dielectric layers has a thickness of about three times the base value;
the second redistribution layers alternate between having a thickness of about twice the base value and about the base value;
each of the second dielectric layers has a thickness of about three times the base value; and
the base value is between about 0.5 microns and about 2 microns.

15. The system of claim 14, wherein:
the base value is about 1 micron;
each of the second vias and the third vias comprises a diameter of about 3 microns; and
each of a plurality of conductive portions of the first redistribution layers contacting the second vias and each of a plurality of conductive portions of the second redistribution layers contacting the third vias comprises a diameter of about 4 microns.

16. The system of claim 13, wherein each stackup of layers further comprises at least one of: one or more embedded resistors, each having a sheet resistance value between about 1 and about 1,000 Ohms/square, or one or more embedded capacitors, each comprising a dielectric material having a dielectric constant between about 1 and about 100.

17. The system of claim 13, wherein the package further comprises:
a package substrate;
a stiffener mounted on the package substrate and positioned at least partially around the interposer; and
a lid attached to the stiffener to define an interior space between the lid, the stiffener, and the package substrate, the one or more semiconductor devices and the interposer positioned within the interior space.

18. The system of claim 17, further comprising:
a printed circuit board on which the package is mounted;
wherein the interposer is configured to facilitate communication between the one or more semiconductor devices and the printed circuit board.

19. The system of claim 13, wherein each stackup of layers comprises a high-density stackup of layers configured to implement a digital communication protocol between at least one of: two or more semiconductor devices or two or more connectors of a single semiconductor device.

20. A method comprising:
obtaining a core comprising a substrate and first vias through the substrate;
forming a first stackup of layers over a first side of the core, the first stackup of layers comprising first redistribution layers and first dielectric layers, the first redistribution layers electrically coupled together using second vias through the first dielectric layers, the first stackup of layers forming a first stripline and a second stripline; and
forming a second stackup of layers over a second side of the core opposite the first side, the second stackup of layers comprising second redistribution layers and second dielectric layers, the second redistribution layers electrically coupled together using third vias through the second dielectric layers, the second stackup of layers forming a third stripline.
